(19) United States
(12) Patent Application Publication
(10) Pub. No.: US 2015/0228591 A1
(43) Pub. Date: Aug. 13, 2015

(54) SEMICONDUCTOR PACKAGE AND METHOD OF MANUFACTURING THE SAME

(71) Applicant: Samsung Electronics Co., Ltd., Suwon-Si (KR)

(72) Inventors: Ji-Hwang KIM, Cheonan-si (KR); Keum-Hee MA, Suwon-si (KR); Tae-Je CHO, Hwaseong-si (KR)

(21) Appl. No.: 14/559,446

(22) Filed: Dec. 3, 2014

(30) Foreign Application Priority Data
Feb. 10, 2014 (KR) 10-2014-0015047

(51) Int. Cl. H01L 23/00; H01L 23/16; H01L 23/367; H01L 23/522

(52) U.S. Cl. CPC H01L 23/562; H01L 23/522; H01L 23/16; H01L 23/367; H01L 24/17; H01L 24/81; H01L 2224/818

(57) ABSTRACT

A semiconductor package including a chip stack structure having first and second chips that are secured to a dissipating plate by using a mold layer such that the second chip is combined to the dissipating plate and the first chip is bonded to the second chip, and the first chip has a smaller thickness than the second chip, a circuit board onto which the chip stack structure is mounted in a bonded manner, and an under-fill layer filling a gap space between the circuit board and first chip, a side surface of the under-fill layer being connected to a sidewall of the mold layer may be provided. Due to this bulk mounting structure, the warpage and bonding failures of the semiconductor package may be substantially reduced.

### CROSS-REFERENCE TO RELATED APPLICATIONS

This application claims priority under 35 U.S.C §119 to Korean Patent Application No. 10-2014-0015047 filed on Feb. 10, 2014 in the Korean Intellectual Property Office, the disclosure of which is incorporated by reference herein in its entirety.

### BACKGROUND

1. Field

Some example embodiments relate to semiconductor packages and methods of manufacturing the same, and more particularly, to chip stack packages and methods of manufacturing the same.

2. Description of the Related Art

Recently, there has been a great demand for semiconductor packages having small size and large capacity. Because the capacity of a memory chip is difficult to increase, there have been efforts to increase the capacity of the semiconductor package, for example, by vertically stacking a plurality of the conventional memory chips (multichip-type package) or by vertically stacking conventional semiconductor packages (stack-type package). In recent small form factor electronic systems, the multichip package is more widely used than the stack package. The multichip package mounts a plurality of the memory chips on a single circuit board, while the stack package uses more than one circuit board, on which respective packages are mounted. Thus, the stack-type package is generally thicker than the multichip-type package.

Further, a penetration electrode such as a through-silicon via (TSV) has been widely used for interconnecting the stacked memory chips in the multichip package in place of a conventional bonding wire. Thus, a space for the bonding wires may not be provided in the multichip package using the TSV and the overall size of the multichip package can be reduced as much as the bonding space. In the conventional multichip packages, a first chip, which is relatively thin and includes the TSV, is mounted on the circuit board, and then a second chip being relatively thick is bonded onto the first chip.

In the conventional multichip packages, the circuit board may experience a warpage while bonding the second chip to the first chip. Accordingly, solder bumps interposed between the circuit board and the first chip may be partially broken, and thus the first chip may not be substantially bonded to the circuit board.

Accordingly, research has been conducted for an improved multichip package in which the circuit board warpage is mitigated or prevented, and thus the first chip can be substantially bonded to the circuit board.

### SUMMARY

At least one example embodiment of the present inventive concepts provides a semiconductor package in which the circuit board is assembled with a chip stack structure, and thus the circuit board warpage is mitigated or prevented in the semiconductor package.

At least one example embodiment of the present inventive concepts provides a method of manufacturing the semiconductor package by assembling the circuit board with the chip stack structure.

According to an example embodiment, a semiconductor package includes a chip stack structure having first and second integrated circuit chips that are secured to a thermal conductive plate using a mold layer such that the second integrated circuit chip is combined to the thermal conducive plate, the first integrated circuit chip is bonded to the second integrated circuit chip, and the first integrated circuit chip has a smaller thickness than the second integrated circuit chip, a circuit board onto which the chip stack structure is mounted in a bonded manner, and an under-fill layer filling a gap space between the circuit board and the first integrated circuit chip, a side surface of the under-fill layer being connected to a sidewall of the mold layer.

In some example embodiments, the first integrated circuit chip may include a wafer level chip having at least one penetration electrode penetrating therethrough and the second integrated circuit chip may include a die level chip having no penetration electrode.

In some example embodiments, the semiconductor package may further include at least one inter-chip connector interposed between the first and the second integrated circuit chips, the inter-chip connector configured to connect the penetration electrode of the first integrated circuit chip with a chip pad of the second integrated circuit chip.

In some example embodiments, the semiconductor package may further include a die adhesive between the first and the second integrated circuit chips to attach the first and the second integrated circuit chips to each other.

In some example embodiments, the thermal conductive plate may include a dissipating plate dissipating heat outwards from at least one of the first and the second integrated circuit chips and a side surface of the thermal conductive plate may be coplanar with the sidewall of the mold layer.

In some example embodiments, the semiconductor package may further include a thermal conductive adhesive for adhering the dissipating plate to the second integrated circuit chip and configured to transfer the heat to the dissipating plate.

In some example embodiments, the semiconductor package may further include a plurality of bump structures interposed between a first chip pad of the first integrated circuit chip and an upper contact pad of the circuit board, the bump structures configured to electrically connect the first integrated circuit chip to the circuit board.

According to an example embodiment of the present inventive concepts, a method of manufacturing the above semiconductor package includes forming a chip stack structure having at least one first integrated circuit chip and at least one second integrated circuit chip, the first and second integrated circuit chips secured to a thermal conductive mother plate by using a mold layer such that the second integrated circuit chip is combined to the thermal conductive mother plate and the first integrated circuit chip having a smaller thickness than the second integrated circuit chip and bonded to the second integrated circuit chip, mounting the chip stack structure onto a circuit board such that the first integrated circuit chip is bonded to the circuit board, and forming an under-fill layer to fill in a gap space between the chip stack structure and the circuit board, a side surface of the under-fill layer being connected to a sidewall of the mold layer.

In some example embodiments, forming the chip stack structure may include combining a plurality of the second integrated circuit chips, which include the at least one second integrated circuit chip, to a thermal conductive mother plate, and forming a plurality of chip assemblies on the thermal conductive mother plate by bonding a plurality of the first integrated circuit chips, which include the at least one first integrated circuit chip, to the second integrated circuit chips, respectively such that at least one penetration electrode penetrating one of the first integrated circuit chips is bonded to the corresponding one of the second integrated circuit chips, forming a mold layer to cover the chip assemblies to secure the chip assemblies to the thermal conductive mother plate, thereby forming a preliminary chip stack structure, and separating the preliminary chip stack structure into pieces by each of the chip assemblies.

In some example embodiments, forming the plurality of the chip assemblies on the thermal conductive mother plate may include forming at least one inter-chip connector on a rear face of one of the first integrated circuit chips such that the inter-chip connector is bonded to the penetration electrode of the one of the first integrated circuit chips, positioning the one of the first integrated circuit chips over a corresponding one of the second integrated circuit chips such that the inter-chip connector of the one of the first integrated circuit chip is aligned with a chip pad of the corresponding one of the second integrated circuit chips, and bonding the inter-chip connector of the one of the first integrated circuit chips to the chip pad of the corresponding one of the second integrated circuit chip.

In some example embodiments, bonding the inter-chip connector may include supplying a die adhesive into an inter-chip gap space between the first and the second integrated circuit chips and performing a thermal compression bonding.

In some example embodiments, forming the mold layer may include covering the chip assemblies with a liquefied epoxy molding compound and hardening the liquefied epoxy molding compound.

In some example embodiments, forming the mold layer may be performed by a single molded under fill (MUF) process in which an inter-chip gap space between the first and the second integrated circuit chips and a side space between the neighboring chip assemblies are filled with a same molding material.

In some example embodiments, the method of manufacturing a semiconductor package may further include, before separating the preliminary chip stack structure into the pieces, forming at least one bump structure on at least one chip pad of the first integrated circuit chips.

In some example embodiments, mounting the chip stack structure onto the circuit board may include coating at least one contact pad of the circuit board with a flux, aligning the bump structure with the contact pad, and bonding the bump structure to the contact pad of the circuit board.

According to some example embodiments of the present inventive concepts, a plurality of integrated circuit chips may be firstly stacked on a dissipating plate and then a chip stack structure of the integrated circuit chip and the dissipating plate may be secondly mounted onto the circuit board so that a plurality of integrated circuit chips may be mounted the circuit board in a bulk. Thus, the warpage of the circuit board and the bonding failures caused by the warpage may be substantially mitigated or prevented and operational reliability of the multichip package may be increased.

According to some example embodiments of the present inventive concepts, a plurality of first integrated circuit chips may be firstly combined to a dissipating plate and a plurality of second integrated circuit chips may be mounted on the first integrated circuit chips, thereby forming a plurality of chip assemblies. Then, the chip assemblies are separated into an individual chip stack structures. Each of the individual chip stack structures may be secondly mounted to the circuit board. Thus, the warpage of the circuit board may be substantially reduced as compared to when the first integrated circuit chip having a relatively small size may be firstly mounted on the circuit board and then the second integrated circuit chip having a relatively large size may be bonded to the first integrated circuit chip. Therefore, the bonding failures of the integrated circuit chips to the circuit board caused by the warpage may be substantially reduced, which may increase reliability of the multichip package 500.

Further, because the chip stack structure 100 including the mold layer may be mounted onto the circuit board, the surface area of the under-fill layer may be increased. Thus, the thermal resistance of the circuit board may be increased in the under-fill process and thus the warpage of the circuit board may be mitigated or prevented in the under-fill process. Further, the mechanical bonding force between the circuit board and the chip stack structure may be increased due to the increase of the surface area of the under-fill layer, which may increase reliability of the semiconductor package.

According to an example embodiment, a semiconductor package may include a chip stack structure including a first semiconductor chip, a second semiconductor chip, a thermal conductive plate, and a mold layer, the second semiconductor chip between the first semiconductor chip and the thermal conductive plate, the first semiconductor chip thinner than the second semiconductor chip, the mold layer covering the first and second semiconductor chips on the thermal conductive plate, a circuit board onto which the chip stack structure is attached such that a chip pad of the first semiconductor chip is coupled to an upper contact pad of the circuit board through a conductive structure, and an under-fill layer filling a gap space between the circuit board and the first semiconductor chip, a side surface of the under-fill layer extending from a sidewall of the mold layer.

In some example embodiments, the second semiconductor chip may be larger than the first semiconductor chip.

In some example embodiments, an upper surface of the mold layer may be coplanar with the chip pad of the first semiconductor chip or stepped over the chip pad.

In some example embodiments, a sidewall of the chip stack structure may be defined by the mold layer which has a substantially vertical shape.

In some example embodiments, the first semiconductor chip may include a wafer level chip, the first semiconductor chip having at least one penetrating electrode penetrating therethrough and the second semiconductor chip includes a die level chip having no penetration electrode.

### BRIEF DESCRIPTION OF THE DRAWINGS

These and other features of the inventive concepts will become more apparent by describing in detail example embodiments thereof with reference to the accompanying drawings of which:

FIG. 1 is a cross-sectional view of a multichip package in accordance with an example embodiment;

FIG. 2 is a cross-sectional view of a another example of the multichip package shown in FIG. 1;

FIGS. 3A to 3G are cross-sectional views illustrating a method of manufacturing the multichip package shown in FIG. 1 in accordance with an example embodiment;

FIG. 4 is a cross-sectional view illustrating a process for forming the preliminary mold layer shown in FIG. 3C, according to another example embodiment;

FIG. 5 is a cross-sectional view illustrating a modified process for forming the preliminary mold layer shown in FIG. 3C, according to still another example embodiment;

FIG. 6 is a block diagram illustrating a memory card having the semiconductor package shown in FIG. 1 or 2 in accordance with an example embodiment; and

FIG. 7 is a block diagram illustrating an electronic system having the multichip package shown in FIG. 1 or 2 in accordance with an example embodiment.

### DETAILED DESCRIPTION

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Hereinafter, example embodiments will be explained in detail with reference to the accompanying drawings.

Multichip Package

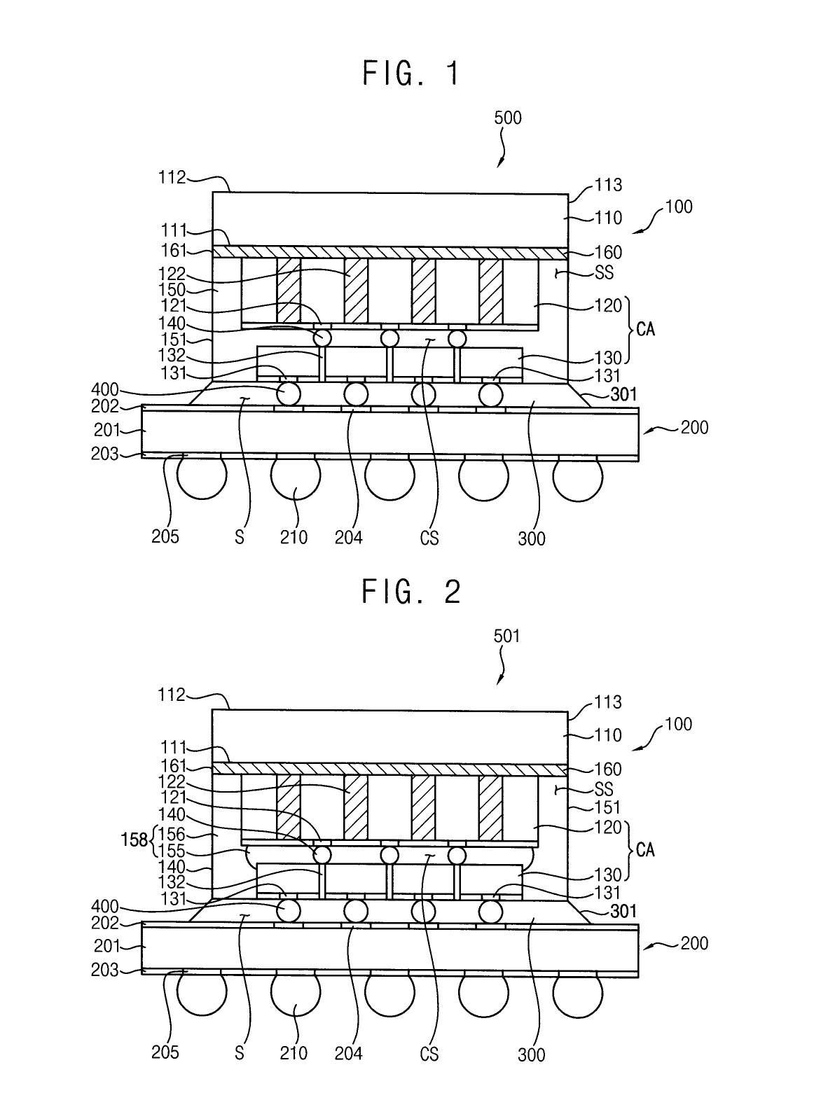

FIG. 1 is a cross-sectional view of a multichip package in accordance with an example embodiment. FIG. 2 is a cross-sectional view of a another example of the multichip package shown in FIG. 1.

Referring to FIG. 1, the multichip package 500 in accordance with an example embodiment may include a chip stack structure 100 having a plurality of integrated chips secured to a thermal conductive plate 110 by using a mold layer 150, a circuit board 200 onto which the chip stack structure 100 may be mounted and an under-fill layer 300 filling up a gap space S between the circuit board 200 and having a side surface 301 connected to a sidewall 151 of the mold layer 150.

For example, the chip stack structure 100 may include first and second integrated circuit chips 130 and 120 that are secured to the thermal conductive plate 110 using the mold layer 150 such that the second integrated circuit chip 120 is on the thermal conductive plate 110 and the first integrated circuit chip 130, which has a smaller thickness than the second integrated circuit chip 120 and is bonded to the second integrated circuit chip 120, are covered by the mold layer 150. The first and the second integrated circuit chips 130 and 120 may be electrically connected to each other such that the first and the second integrated circuit chips 130 and 120 may be provided as a chip assembly CA on the thermal conductive plate 110. The mold layer 150 may secure the chip assembly CA to the thermal conductive plate 110 and encapsulate the chip assembly CA from surroundings.

The thermal conductive plate 110 may have sufficient thickness and rigidity and/or may have, for example, a flat plate shape so as to stably combine with the chip assembly CA and the mold layer 150. For example, the thermal conductive plate 110 may comprise a material having high thermal conductivity, for example, copper (Cu), copper alloy, aluminum, aluminum alloy, steel, stainless steel and combinations thereof. In contrast, the thermal conductive plate 110 may also comprise one of insulation materials and semiconductor materials.

For example, the thermal conductive plate 110 may have the flat plate formed by one of a casting process, a forging process and a press working Heat from the chip assembly CA may be dissipated through the thermal conductive plate 110. Thus, the thermal conductive plate 110 may function as a dissipating plate in the multichip package 500. Hereinafter, the dissipating plate and the thermal conductive plate may be interchangeably used to refer to the element designated by the reference numeral 110. The dissipating plate 110 may include a contact face 111 making contact with the chip assembly CA and a dissipating face 112 from which the heat may be dissipated outwards.

The contact face 111 may be a flat plane, and thus the chip assembly CA may make contact with an entire surface of the dissipating plate 110. In contrast, the dissipating face 112 may be a curved or uneven plane to have an expanded a dissipating surface. For example, a plurality of protrusions (not shown) may protrude from the dissipating face 112, and thus the dissipating surface may be expanded as much as the surfaces of the protrusions.

A heat spreader (not shown) may be further provided on the dissipating face 112 such that the thermal conductive plate 110 may be covered with the heat spreader. The heat spreader may protect the thermal conductive plate 110 from external shocks or impacts.

The second and the first integrated circuit chips 120 and 130 may be sequentially stacked on the contact face 111 of the dissipating plate 110. The first and the second integrated circuit chips 130 and 120 may include semiconductor chips (e.g., memory chips and logic chips) manufactured by a series of semiconductor manufacturing processes.

For example, the first and the second integrated circuit chips 130 and 120 may include the memory chips and/or the logic chips. That is, one of the first and the second integrated circuit chips 130 and 120 may include the memory chip and the other one may include the logic chip. The logic chip may include a microprocessor, for example, a central processing unit (CPU), a controller and an application specific integrated circuit (ASIC) chip. In addition, the logic chip may also include an application processor chip for operating a mobile system (e.g., a smart phone, an MP3 player, a navigation system and a personal multimedia player (PMP)). The memory chip may include a volatile memory chip (e.g., a dynamic random access memory (DRAM) chip and a static random access memory (SRAM) chip) and a non-volatile memory chip (e.g., a flash memory chip). For example, the memory chip may include a double data rate (DDR) synchronous dynamic random access memory (SDRAM) chips for the mobile system.

The first and the second integrated circuit chips 130 and 120 may include a wafer level chip so as to reduce the stack space and increase a packaging density. For example, the first integrated circuit chip 130 may include the wafer level chip as the logic chip and the second integrated circuit chip 120 may include a die level chip as the memory chip such that the second integrated circuit chip 120 may be combined with the dissipating plate 110 and the first integrated circuit chip 130 may be bonded to the second integrated circuit chip 120. In a process for forming the wafer level chip, an inter-chip connector (e.g., bump structures) and penetrating electrodes for a chip stack may be formed at each chip on a wafer before slicing the wafer into individual dies. In contrast, in a process for forming the die level chip, the inter-chip connector may be formed at each chip after slicing the wafer into individual dies. Accordingly, the inter-chip connector of the die level chip may be formed on the individual dies in a separate packaging process.

In the present example embodiment, the first integrated circuit chip 130 may include the wafer level chip having a penetrating electrode 132 and the second integrated circuit chip 120 may include the die level chip without the penetrating electrode. Further, a rear surface of the wafer having the first integrated circuit chip 130 may be polished such that the first integrated circuit chip 130 has a smaller thickness than that of the second integrated circuit chip 120.

The penetrating electrode 132 may include a through-silicon via (TSV) penetrating the silicon wafer having the first integrated circuit chip 130. Accordingly, a bonding space (e.g., a space for bonding wires) for stacking another integrated circuit chip on the first integrated circuit chip 130 may be substantially reduced as compared with the die level chip, thereby reducing a size of the multichip package 500.

The penetrating electrode 132 may be directly bonded to a first chip pad 131, which may be arranged on an active face of the first integrated circuit chip 130, or may be located away from the first chip pad 131 and be indirectly connected to the first chip pad 131 by a wiring, for example, a re-directional line. The penetrating electrode 132 may comprise metal materials having high electrical conductivity. Examples of the highly electrically conductive metal may include, for example, silver (Ag), gold (Au), copper (Cu), nickel (Ni), palladium (Pa), or platinum (Pt). These may be used alone or in combinations thereof. A barrier metal layer (not shown) may be further interposed between the penetrating electrode 132 and the wafer through which the penetrating electrode 132 penetrates. Accordingly, the metal may be substantially mitigated or prevented from being diffused into the wafer in a process for forming the penetrating electrode 132.

The second integrated circuit chip 120 may make contact with the dissipating plate 110 such that the operation heat generated from the second integrated circuit chip 120 may be dissipated outwards through the dissipation plate 110. Further, the second integrated circuit chip 120 may be electrically connected to the penetrating electrode 132 of the first integrated circuit chip 130. In the present example embodiment, the second integrated circuit chip 120 may have a larger thickness than the first integrated circuit chip 130, which is bonded to the circuit board 200, and may generate the operation heat greater than the first integrated circuit chip 130. For these reasons, the second integrated circuit chip 120 may be desired to have improved heat dissipation characteristics than the first integrated circuit chip 130.

The present example embodiment discloses that the second integrated circuit chip 120 may include the die level chip and thus the thickness of the second integrated circuit chip 120 may be greater than the first integrated circuit chip 130. However, even though the second integrated circuit chip 120 may include the wafer level chip, the second integrated circuit chip 120 may still be configured to make contact with the dissipating plate 110 as long as the second integrated circuit chip 120 may have greater thickness than the first integrated circuit chip 130 and thus the heat from the second integrated circuit chip 120 may be still larger than that of the first integrated circuit chip 130.

After combining the second integrated circuit chip 120 and the dissipating plate 110, the relatively small-sized first integrated circuit chip 130 may be bonded to the second integrated circuit chip 120. The chip stack structure 100, in which the first integrated circuit chip 130 is bonded to the second integrated circuit chip 120, may be mounted onto the circuit board 200. In the conventional multichip packages, a relatively small-sized logic chip is firstly mounted onto the circuit board, a relatively large-sized memory chip is bonded to the small-sized logic chip, and finally the dissipating plate may adhere to the memory chip. Thus, the warpage defect may occur in the circuit board of the conventional multichip package, and thus bonding between the memory chip and the logic chip and bonding between the circuit board and the logic chip may deteriorate or be broken. However, in the present example embodiment of the semiconductor package, the chip stack structure 100 including the first and the second integrated circuit chips 130 and 120 may be mounted onto the circuit board 200 such that the relatively small-sized first integrated circuit chip 130 may be bonded to the circuit board 200. Thus, the warpage of the circuit board 200 may be minimized.

That is, the first and the second integrated circuit chips 130 and 120 may be bonded to the circuit board 200 as the chip assembly CA by a single mounting process (instead of the mounting process for mounting the logic chip to the circuit board and the bonding process for bonding the memory chip to the logic chip), thereby decreasing the warpage of the circuit board 200. For example, because the relatively large-sized chip may be mitigated or prevented from being bonded to the relatively small-sized chip, a bonding failure between the first and the second integrated circuit chips 130 and 120 may be minimized or prevented.

The first and the second integrated circuit chips 130 and 120 may be bonded to each other by the inter-chip connector 140. The inter-chip connector 140 may mechanically bond and electrically connect the first and the second integrated circuit chips 130 and 120 with each other. For example, the inter-chip connector 140 may include, for example, a solder bump or a solder paste having good electrical conductivity.

For example, the inter-chip connector 140 may make contact with both of the penetrating electrode 132 and the second chip pad 121 of the second integrated circuit chip 120. Thus, the second integrated circuit chip 120 may be electrically connected to the first integrated circuit chip 130 via the penetrating electrode 132. In the present example embodiment, because no penetrating electrode may be provided in the second integrated circuit chip 120, the inter-chip connector 140 may be bonded to the second chip pad 121 of the second integrated circuit chip 120. However, in case that additional penetrating electrode is provided in the second integrated circuit chip 120, the inter-chip connector 140 would be interposed between the penetrating electrode 132 of the first integrated circuit chip 130 and the additional penetrating electrode of the second integrated circuit chip 120.

The first and the second integrated circuit chips 130 and 120 may be arranged in a flip chip structure such that the active faces of the first and the second integrated circuit chips 130 and 120 may face the circuit board 200. However, various modifications may be allowable to the chip arrangement.

For example, when the additional penetrating electrode (not shown) may be provided with the second integrated circuit chip 120, the second integrated circuit chip 120 may be combined to the first integrated circuit chip 130 in a face-up structure. For example, the inter-chip connector 140 may be interposed between the penetrating electrode 132 of the first integrated circuit chip 130 and the additional penetrating electrode of the second integrated circuit chip 120. Accordingly, the rear face of the first integrated circuit chip 130 may face that of the second integrated circuit chip 120. For example, when the second integrated circuit chip 120 may include a plurality of stacked memory chips and each of the memory chips may include its own penetrating electrodes, each of the memory chips may be arranged on the first integrated circuit chip 130 irrespective of the face-up or face-down structure of each memory chip.

In some example embodiments, when the second integrated circuit chip 120 is bonded to the first integrated circuit chip 130 in the face-down structure or the flip chip structure, a thermal via 122 may be further provided in the second integrated circuit chip 130 so that heat may be efficiently transferred to the dissipating plate 110 through the thermal via 122.

The thermal via 122 may function as a heat transfer path in the second integrated circuit chip 120, but may not be connected to wirings of the second integrated circuit chip 120. Thus, although the heat source of the second integrated circuit chip 120 may be closer to the first integrated circuit chip 130 rather than to the dissipating plate 110 due to the flip chip structure of the second integrated circuit chip 120 with respect to the first integrated circuit chip 130, the operation heat of the second integrated circuit chip 120 may be efficiently transferred to the dissipating plate 110 through the thermal via 122.

While the present example embodiment discloses a single memory chip as the second integrated circuit chip 120, a plurality of the memory chips may also be provided as the second integrated circuit chip 120 according to some example embodiments. In such a case, a plurality of die level memory chips may be stacked on the wafer level logic chip, thereby increasing the memory capacity of the multichip package 500.

The first integrated circuit chip 130 bonded to the second integrated circuit chip 120 may be provided as the chip assembly CA and the chip assembly CA may be arranged on the dissipating plate 110. The chip assembly CA may be stably secured to the dissipating plate 110 by the mold layer 150. The mold layer 150 may also protect the chip assembly CA from external impacts and shocks.

The mold layer 150 may include an insulating resin covering an entire surface of the dissipating plate 110 to a thickness sufficient to cover the chip assembly CA on the dissipating plate 110. The mold layer 150 may include a thermosetting resin, for example, a mixture of an epoxy resin, the silicate, catalyst and coloring matters. In some example embodiments, the mold layer 150 may include the epoxy resin containing epoxy molding compound (EMC).

For example, the mold layer 150 may include a single mold that may be formed by a single molding process such as a molded under fill (MUF) process, so that an inter-chip space CS between the first and the second integrated circuit chips 130 and 120 and a side space SS between a pair of the neighboring chip assemblies CA may be simultaneously filled with the mold layer 150. In the MUF process, a liquefied EMC may flow into the inter-chip space CS and the side space SS on the dissipating plate 110 until the chip assembly CA may be substantially covered with the liquefied EMC. Thereafter, the liquefied EMC may be hardened for a desired time to mitigate or prevent void defects in the mold layer 150. For example, the MUF process may reduce the voids in the mold layer 150 filling the inter-chip space CS, thereby mitigating or preventing deterioration of a mechanical bonding force of the inter-chip connector 140 and thus increasing bonding reliability of the chip assembly CA in the chip stack structure 100. In such a case, the inter-chip connector 140 may be interposed between the second chip pad 121 of the second integrated circuit chip 120 and the penetrating electrode 132 of the first integrated circuit chip 130.

In contrast, the inter-chip space CS may be filled with materials different from the material filling the side space SS of the chip assembly CA, as shown in FIG. 2. According to a modified multichip package 501 in FIG. 2, the inter-chip space CS may be filled with a die adhesive 155 and the side space SS of the chip assembly CA may be filled with an outer mold layer 156. That is, the modified multichip package 501 may include a modified mold layer 158 having the die adhesive 155 and the outer mold layer 156.

The die adhesive 155 may make the first integrated circuit chip 130 to adhere to the second integrated circuit chip 120 such that the first and the second integrated circuit chips 130 and 120 may be mechanically combined with each other by the bonding force of the inter-chip connector 140 and the adhesive force of the die adhesive 155. Thus, the bonding reliability between the first and the second integrated circuit chips 130 and 120 may be increased by the die adhesive 155. For example, the die adhesive 155 may be coated on the active face of the second integrated circuit chip 120 and the first integrated circuit chip 130 may be located over the second integrated circuit chip 120 such that the inter-chip connector 140 bonding to the penetrating electrode 132 may be aligned with the second chip pad 121. Thereafter, the first integrated circuit chip 130 may adhere to the second integrated circuit chip 120 by a thermal compression bonding process such that the inter-chip connector 140 is bonded to the second chip pad 121.

An upper surface of the mold layer 150 may be coplanar with the first chip pad 131 of the first integrated circuit chip 130 or may be stepped over from the first chip pad 131. When the mold layer 150 is formed to be stepped over the first chip pad 131, the mold layer 150 may be formed to have a thickness sufficient to cover the first chip pad 131 and may have an opening through which the first chip pad 131 is exposed. A bump structure 400 may be provided on the exposed first chip pad 131.

A dissipating adhesive 160 may be interposed between the second integrated circuit chip 120 and the dissipating plate 110 such that the second integrated circuit chip 120 may adhere to the dissipating plate 110. The dissipating adhesive 160 may comprise insulating materials, for example, epoxy resin, polyimide and permanent photoresist. For example, the dissipating adhesive 160 may include a dissipating agent that may fill grooves at boundary surfaces between the second integrated circuit chip 120 and the dissipating plate 110 and between the mold layer 150 and the dissipating plate 110 and may transfer the heat from the second integrated circuit chip 120 to the dissipating plate 110.

For example, the dissipating agent may include, for example, thermal interface materials (TIM), a metal past and nano-sized particles. For example, when electrical conductive materials are mixed up into the dissipating adhesive 160, the dissipating adhesive 160 may be connected to a ground circuit of the multichip package 500, thereby improving the electromagnetic interference (EMI) characteristics and noise characteristics of the multichip package 500.

In the present example embodiment, the sidewall 151 of the mold layer 150, a side surface 161 of the dissipating adhesive 160 and a side surface 113 of the dissipating plate 110 may be coplanar with one another. As described hereinafter, the dissipating adhesive 160 may be coated on a mother plate for the dissipating plate 110 and a plurality of the chip assemblies CA may adhere to the mother plate by using the dissipating adhesive 160. Then, the mold layer 150 may be formed on an entire surface of the mother board to a thickness sufficient to cover the chip assemblies CA. Thereafter, the mold layer 150, the dissipating adhesive 160 and the mother plate may be separated into pieces by each of the chip assemblies CA, to thereby form the chip stack structure 100. Therefore, the sidewall 151 of the mold layer 150, the side surface 161 of the dissipating adhesive 160 and the side surface 113 of the dissipating plate 110 may be sliced to the chip stack structure 100 at the same time such that the sidewall 151 of the mold layer 150, the side surface 161 of the dissipating adhesive 160 and the side surface 113 of the dissipating plate 110 are coplanar with one another.

The circuit board 200 may include a board body 201, which is formed of a rigid plate, and comprise, for example, insulating and heat-resistive materials. A plurality of circuit patterns (not shown) may be arranged in the board body 201 and may be insulated from one another by upper and lower insulation layers 202 and 203. The circuit pattern may be connected upper contact pads 204 and lower contact pads 205, which are electrically insulated from one another by the upper and the lower insulation layers 202 and 203, respectively. The chip stack structure 100 may be connected to the circuit pattern via the upper contact pad 204 and external bodies (not shown) may be connected to the circuit pattern via the lower contact pad 205. For example, a contact terminal 210 such as a solder ball may be bonded to the lower contact pad 205, and the external bodies may make contact with the contact terminal 210.

For example, the board body 201 may include a thermosetting plastic plate (e.g., an epoxy resin plate and a polyimide plate). The board body 201 may include a plate on which a heat-resistive organic film (e.g., a liquid crystal polyester film and a polyamide film) is coated. The circuit pattern may include a plurality of conductive lines or wirings that may be arranged in the board body 201, and may include a power line for applying an electric power, a plurality of signal lines for communicating data signals with the chip stack structure 100, and a ground line for electrically grounding the signal lines and the power line. The conductive lines or the wirings of the circuit pattern may be electrically insulated from one another by the insulating layers 202 and 203. The circuit board 200 may include a printed circuit board (PCB) in which the circuit pattern is formed by a printing process.

The chip stack structure 100 may be bonded to the circuit board by a plurality of conductive bump structures 400 interposed between the first chip pad 131 and the upper contact pads 204. Thus, the chip stack structure 100 may be electrically connected to the circuit pattern of the circuit board 100 via the conductive bump structures 400 and the upper contact pad 204. A gap space S between the chip stack structure 100 and the circuit board 200 may be filled with the under-fill layer 300. In such a case, a side surface 301 of the under-fill layer 300 may be extended from the sidewall 151 of the mold layer 150. Therefore, the chip stack structure 100 may be stably secured to the circuit board 200 by the conductive bump structures 400 and the under-fill layer 300.

The under-fill layer 300 may include a resin layer that may be filled into the gap space S by a capillary under-fill process. For example, the resin layer for the under-fill layer 300 may include, for example, a mixture of an epoxy or a urethane based resin, a hardening agent and a filler for heat transfer. The mixture may be liquefied under high temperature and may be infiltrated into the gap space S by a capillary, and then the liquefied mixture in the gap space S may be hardened. Because the first integrated circuit chip 130 may be covered with the mold layer 150, the side surface 301 of the under-fill layer 300 may be extended from the sidewall 151 of the mold layer 150, not from a side portion of the first integrated circuit chip 130. That is, the side surface 301 of the under-fill layer 300 may be connected to the sidewall 151 of the mold layer 150.

The bump structure 400 may include a solder bumps that may be bonded to the first chip pads 131 of the first integrated circuit chip 130 by a reflow process. The bump structure 400 may also be bonded to the upper contact pads 204 of the circuit board 200. Accordingly, the chip stack structure 100 may be electrically connected to the circuit pattern of the circuit board 200. The external body (not shown), for example, a system board of an electronic system may make contact with the contact terminal 210 and thus the external body may be electrically connected to the circuit pattern via the lower contact pads 205.

According to some example embodiments, a plurality of integrated circuit chips may be stacked on the dissipating plate instead of the circuit board such that a relatively large-sized chip (e.g., a memory chip) may be combined to the dissipating plate and a relatively small-sized chip (e.g., a logic chip) may be bonded to the relatively large-sized chip, thereby providing the chip stack structure. Then, the chip stack structure may be bonded to the circuit board such that the relatively small-sized chip may be bonded to the contact pad of the circuit board. Therefore, the warpage of the circuit board and the bonding failure between the relatively large-sized chip and the relatively small-sized chip may be substantially mitigated or prevented, thereby increasing reliability of the semiconductor package in which a plurality of the integrated circuit chips is stacked.

When the relatively small-sized logic chip is firstly bonded to the circuit board and the relatively large-sized memory chip is bonded to the relatively small-sized logic chip as in the packaging process for the conventional multichip package, the circuit board may be warped by thermal expansions. Accordingly, the bonding of the bump structure between the logic chip and the circuit board and the bonding of the inter-chip connector between the logic chip and the memory chip may deteriorate or be broken due to the circuit board warpage.

According to some example embodiments, however, the relatively large-sized memory chip may be firstly combined to the dissipating plate, of which the rigidity and the thermal resistance may be higher than the circuit board, and then the relatively small-sized logic chip may be bonded to the relatively large-sized memory chip, and finally the circuit board may be combined with the chip assembly, which includes the relatively small-sized logic chip and the relatively large-size memory chip. Thus, the circuit board may undergo a single mounting process with the relatively small-sized logic chip. Therefore, the bonding failures between the relatively small-sized logic chip and the relatively large-sized memory chip may be mitigated or prevented. Further, mounting the chip stack structure to the circuit board by the single mounting process may reduce or prevent the circuit board warpage. Accordingly, the warpage defect of the circuit board and the bonding failures between the stacked chips may be substantially reduced or prevented, thereby increasing reliability of the semiconductor package.

Method of Manufacturing the Multichip Package

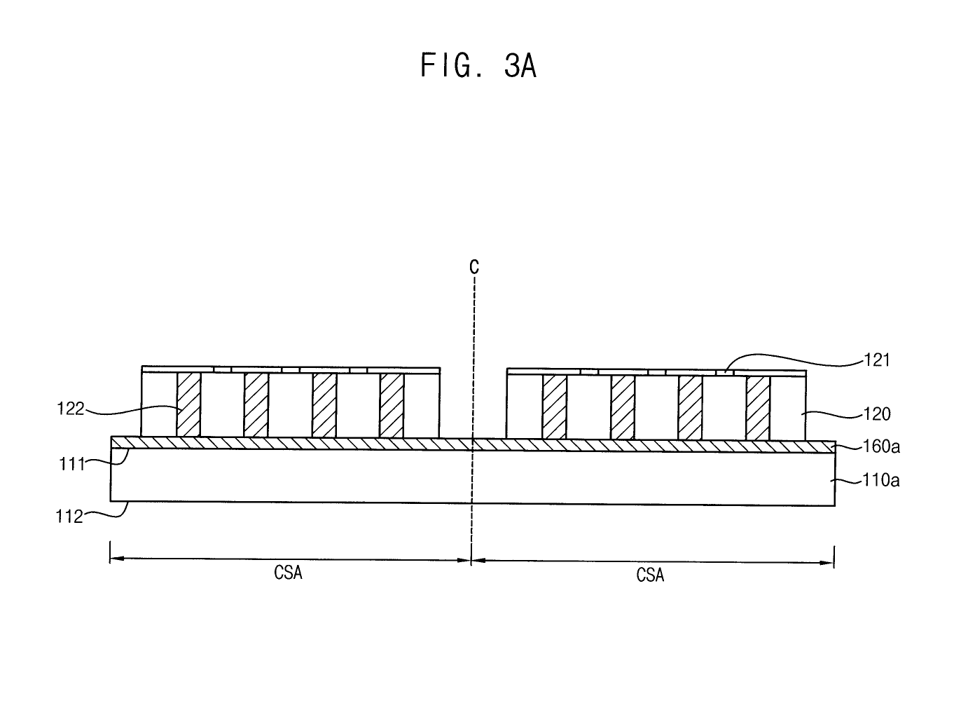

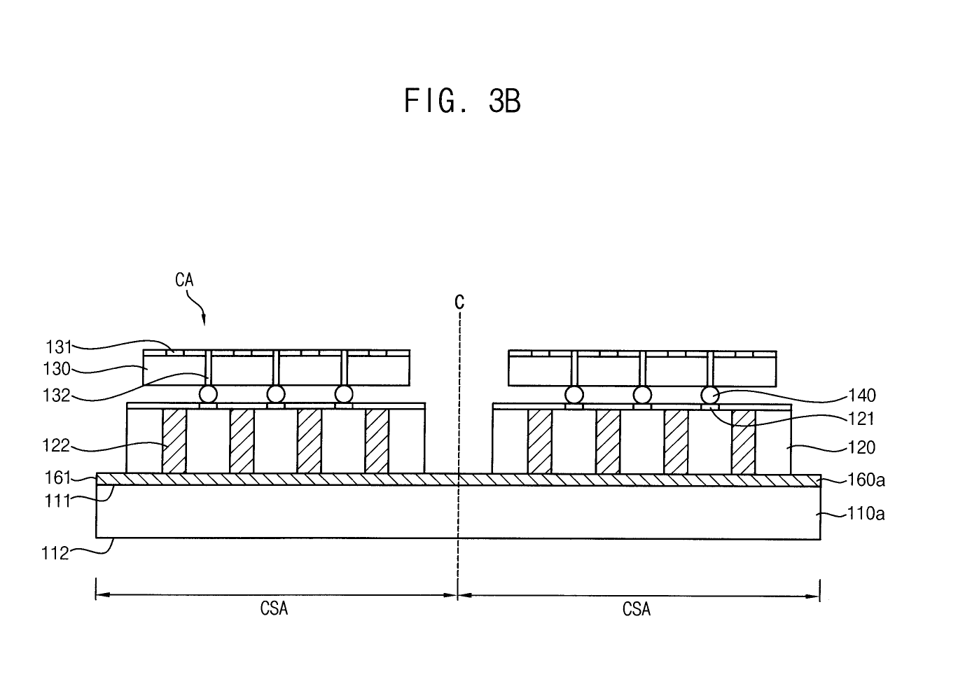

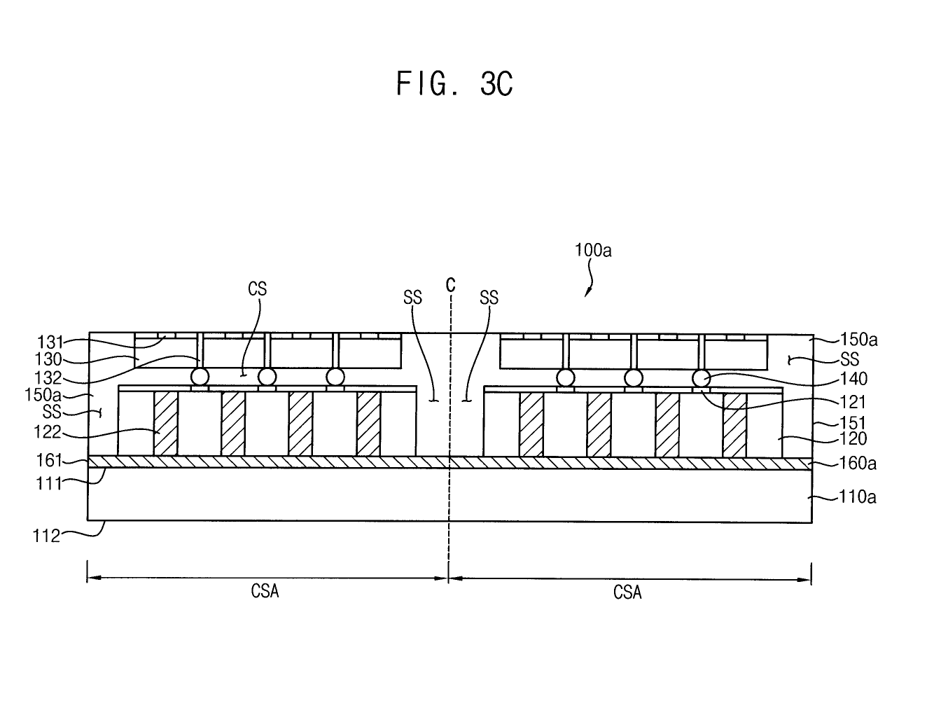

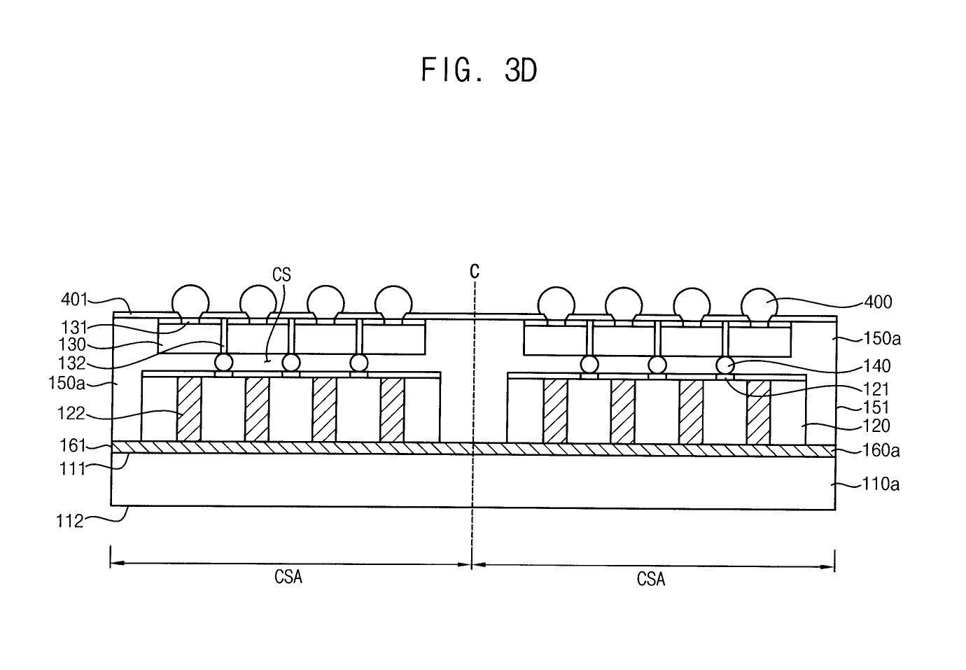

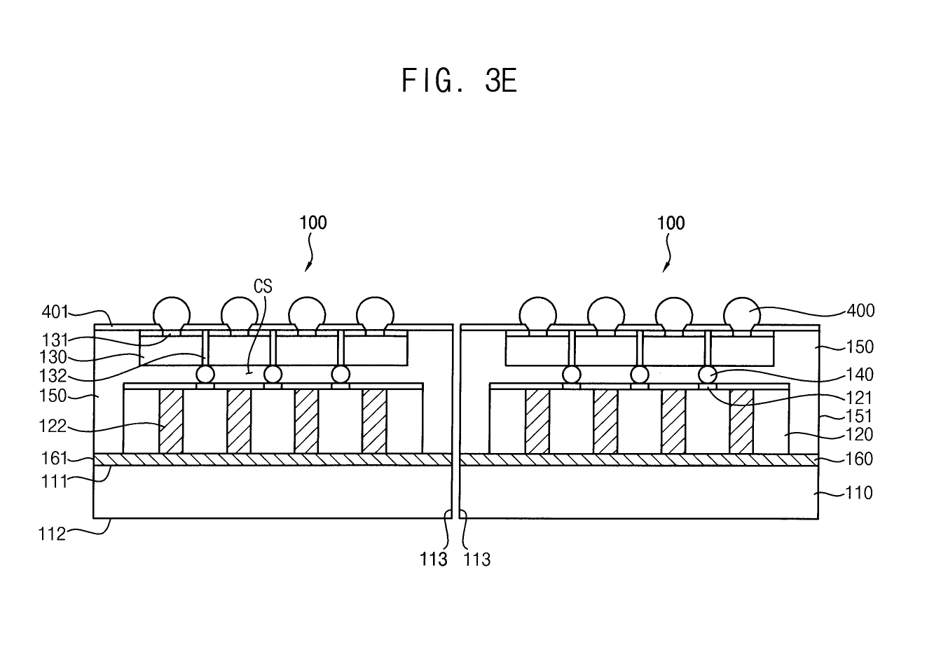

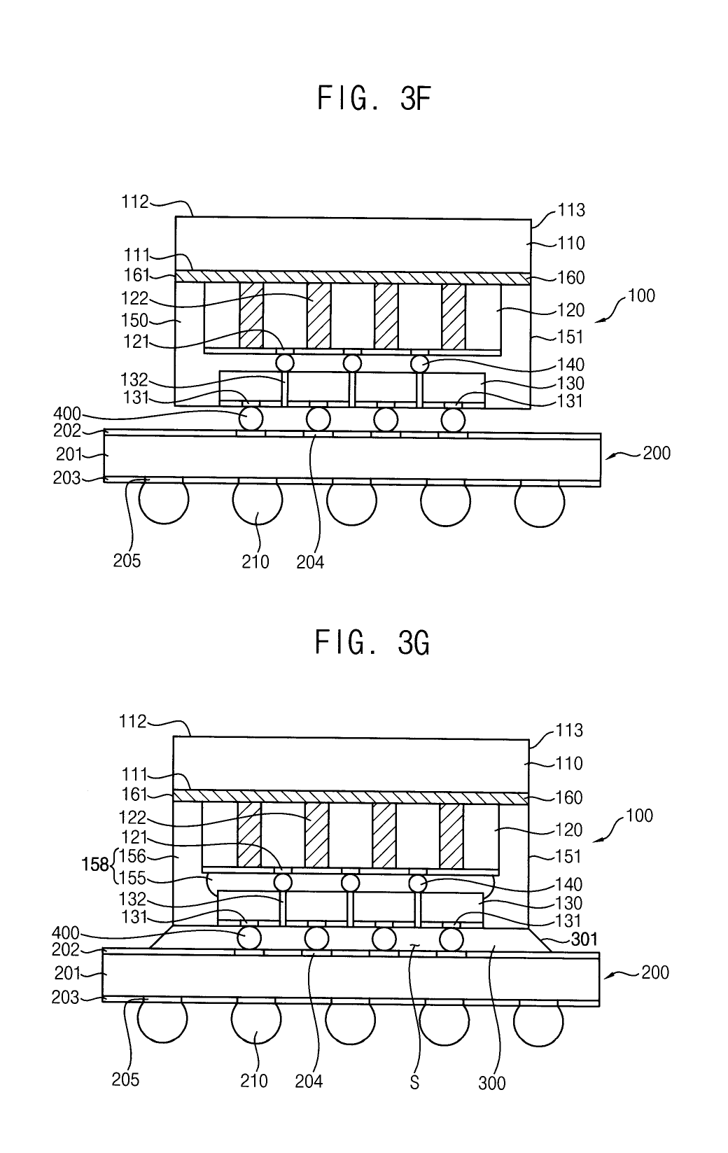

FIGS. 3A to 3G are cross-sectional views illustrating a method of manufacturing the multichip package shown in FIG. 1 in accordance with an example embodiment.

Referring to FIG. 3A, a plurality of the second integrated circuit chips 120 may be combined to a thermal conductive mother plate 110a.

For example, a relatively large-sized flat plate may be provided as the thermal conductive mother plate 110a and a preliminary adhesive 160a may be coated on an entire surface of the thermal conductive mother plate 110a. The thermal conductive mother plate 110a may include a metal plate having high thermal conductivity and high thermal resistance. For example, the thermal conductive mother plate 110a may include, for example, copper (Cu), copper (Cu) alloy, aluminum (Al), aluminum (Al) alloy, steel (Fe), stainless steel and combinations thereof. The thermal conductive mother plate 110a may also include an insulating plate. The thermal conductive mother plate 110a may have a thickness sufficient to resist thermal distortions caused by subsequent bonding processes of the integrated circuit chips.

The thermal conductive mother plate 110a may include a contact face 111 to which the second integrated circuit chip 120 adheres and a dissipating face 112 from which the heat generated from the integrated circuit chips may be dissipated outwards. In the present example embodiment, the dissipating face 112 may have a planar shape. However, the dissipating face 112 may have various shapes to improve heat dissipation efficiency.

The thermal conductive mother plate 110a may be divided into a plurality of chip stack area CSA in which the integrated circuit chips may be stacked. The neighboring chip stack areas CSA may be separated from each other by a scribe line or a cutting line C. Thus, a plurality of chip assembly CA may be stacked at each of the chip stack areas CSA of the thermal conductive mother plate 110a.

The preliminary adhesive 160a may be coated on the entire contact face of the thermal conductive mother plate 110a. A fluidal mixture of insulation materials (e.g., epoxy resin, polyimide and permanent photoresist) and dissipating agents (e.g., thermal interface materials (TIM), a metal past and nano-sized particles) may be coated on the entire contact face 111 of the thermal conductive mother plate 110a, thereby forming the preliminary adhesive on the thermal conductive mother plate 110a.

The second integrated circuit chip 120 may be arranged on the preliminary adhesive 160a at each chip stack area CSA of the thermal conductive mother plate 110a and may adhere to the thermal conductive mother plate by the preliminary adhesive 160a. For example, the second integrated circuit chip 120 may be repeatedly positioned on the preliminary adhesive 160a at every chip stack area C SA of the thermal conductive mother plate 110a such that the active face of the second integrated circuit chip 120 may face upwards. The size of the thermal conductive mother plate 110a may vary according to an allowable size of a mounting apparatus for mounting integrated circuit chips onto a board or a substrate.

In the present example embodiment, the second integrated circuit chip 120 may be combined to the thermal conductive mother plate 110a in the face-up structure and may have a larger size than the first integrated circuit chip 130 that may be bonded to the second integrated circuit chip 120 in a subsequent process. Further, the second integrated circuit chip 120 may include a dissipating via 122 to increase heat dissipation efficiency. Thus, the second integrated circuit chip 120 may be arranged on the thermal conductive mother plate 110a in the face-up structure such that the rear face of the second integrated circuit chip 120 may make contact with the thermal conductive mother plate 110a and the active face thereof may not make contact with the thermal conductive mother plate 110a. In such a case, the operation heat of the second integrated circuit chip 120 may be efficiently transferred to the thermal conductive mother plate 110a through the dissipating via 122.

When a plurality of the second integrated circuit chips 120 may be positioned on the preliminary adhesive 160a at respective chip stack areas CSAs of the thermal conductive mother plate 110a, the preliminary adhesive 160a may be hardened for a desired time. Thus, each of the second integrated circuit chips 120 may adhere to the thermal conductive mother plate 110a at each chip stack area CSA.

Referring to FIG. 3B, a plurality of chip assemblies CA may be formed at respective chip stack areas CSAs of the thermal conductive mother plate 110a by bonding a first integrated circuit chip 130 to the second integrated circuit chip 120 such that at least one penetration electrode 132 penetrating the first integrated circuit chip 130 may be bonded to the second integrated circuit chip 120.

The first integrated circuit chip 130 may have at least one penetrating electrode 132 and at least one inter-chip connector 140 connected to the penetrating electrode 132 in a wafer level packaging process. For example, a solder bump may be formed on a rear face of the first integrated circuit chip 130 as the inter-chip connector 140 such that the solder bump may be bonded to the penetrating electrode 132.

For example, the penetrating electrode 132 may be exposed from the rear face of the first integrated circuit chip 130 and then a seed layer may be formed on the rear face by a sputtering process to make contact with the exposed penetrating electrode 132. The seed layer may be patterned into a seed pattern on the penetrating electrode 132 and then conductive materials may be electroplated on the seed pattern, to thereby form the inter-chip connector 140. The conductive material may include, for example, copper (Cu) and lead (Pb). Thus, the inter-chip connector 140 may be a solder bump or a copper bump.

The penetrating electrode 132 may penetrate through the first chip pad 131 on the active face of the first integrated circuit chip 130. The penetrating electrode 132 may penetrate through the integrated circuit chip 130 spaced apart from the first chip pad 131 and the connected to the first chip pad 131 by a metal wiring. In the present example embodiment, the inter-chip connector 140 may be bonded to an end portion of the penetrating electrode 132 at the rear face of the first integrated circuit chip 130. However, the configurations and the locations of the inter-chip connector 140 may vary according to configurations of the penetrating electrode 132.

Thereafter, the first integrated circuit chip 130 having the inter-chip connector 140 may be moved and positioned over the second integrated circuit chip 120, which is combined to the thermal conductive mother plate 110a, by using a conventional mounting apparatus. For example, the thermal conductive mother plate 110a, to which the second integrated circuit chip 120 is combined at a corresponding chip stack area CSA, may be secured to a mounting table and the first integrated circuit chip 130 having the penetrating electrode 132 may be moved and positioned over the second integrated circuit chip 130 by a chip transfer system. In such a case, the inter-chip connector 140 of the first integrated circuit chip 130 may be aligned with the second chip pad 121 of the second integrated circuit chip 120. Then, the first integrated circuit chip 130 may move downwards by the transfer system until the inter-chip connector 140 may make contact with the second chip pad 121 and a reflow process and a hardening process may be sequentially performed in a thermal treating chamber. As a result, the inter-chip connector 140 of the first integrated circuit chip 130 may be bonded to the second chip pad 121 of the second integrated circuit chip 120.

Thus, the first and the second integrated circuit chips 130 and 120 may be bonded by the inter-chip connector 140, to thereby form the chip assembly CA at each chip stack area CSA of the thermal conductive mother plate 110a.

Because the second integrated circuit chip 120 having a relatively large size is firstly combined to the thermal conductive mother plate 110a, which has relatively high rigidity and thermal resistance, and then the first integrated circuit chip 130 having relatively small size is bonded to the second integrated circuit chip 120, the bonding failures between the first and the second integrated circuit chips 130 and 120 may be substantially reduced as compared with when the second integrated circuit chip 120 having a relatively large size is bonded to the first integrated circuit chip 120 having a relatively small size as in the conventional multichip packaging process.

Referring to FIG. 3C, a preliminary mold layer 150a may be formed on the thermal conductive mother plate 110a to a thickness sufficient to cover the chip assemblies CA such that the chip assemblies CA may be secured to the thermal conductive mother plate 110a at each chip stack area CSA by the mold layer 150 to form a preliminary chip stack structure 100a.

For example, an insulating resin may be coated on the entire contact face 111 of the thermal conductive mother plate 110a to a thickness sufficient to cover the chip assembly CA on the thermal conductive mother plate 110a as the preliminary mold layer 150a. The insulating resin may include a thermosetting resin, for example, a mixture of an epoxy resin, the silicate, catalyst and coloring matters. In some example embodiments, the preliminary mold layer 150a may include, for example, an epoxy resin containing epoxy molding compound (EMC).

For example, the preliminary mold layer 150a may be formed on the thermal conductive mother plate 110a by a single molded under fill (MUF) process in which an inter-chip gap space CS between the first and the second integrated circuit chips 130 and 120 and an side space SS between the neighboring chip assemblies CA are simultaneously filled with the preliminary mold layer 150a. In the MUF process, a liquefied EMC may be supplied into the inter-chip gap space CS between the first and the second integrated circuit chips 130 and 120 and the side space SS between the neighboring chip assemblies CA and then a hardening process may be performed to the liquefied EMC. Thus, the inter-chip gap space CS and the side space SS may be simultaneously filled up with the EMC as the preliminary mold layer 150a. Therefore, void defects may be minimized in the preliminary mold layer 150a. Because the MUF process may reduce the voids in the preliminary mold layer 150a filling the inter-chip space CS, the MUF process may mitigate or prevent deterioration of the mechanical bonding force of the inter-chip connector 140, and thus may improve bonding reliability of chip assembly CA.

An exposed MUF (e-MUF) process (e.g., a process of removing a portion of the preliminary mold layer 150a to expose the first chip pad 131) may be performed on the combination of the chip assembly CA and the thermal conductive mother plate 110a. In the present example embodiment, however, an upper surface of the preliminary mold layer 150a may be coplanar with an upper surface of the first chip pad 131 of the first integrated circuit chip 130. Thus, no additional patterning process to expose the first chip pad 131 needs to be performed.

In contrast, the inter-chip space CS may be filled with materials different from those of the side space SS of the chip assembly CA.

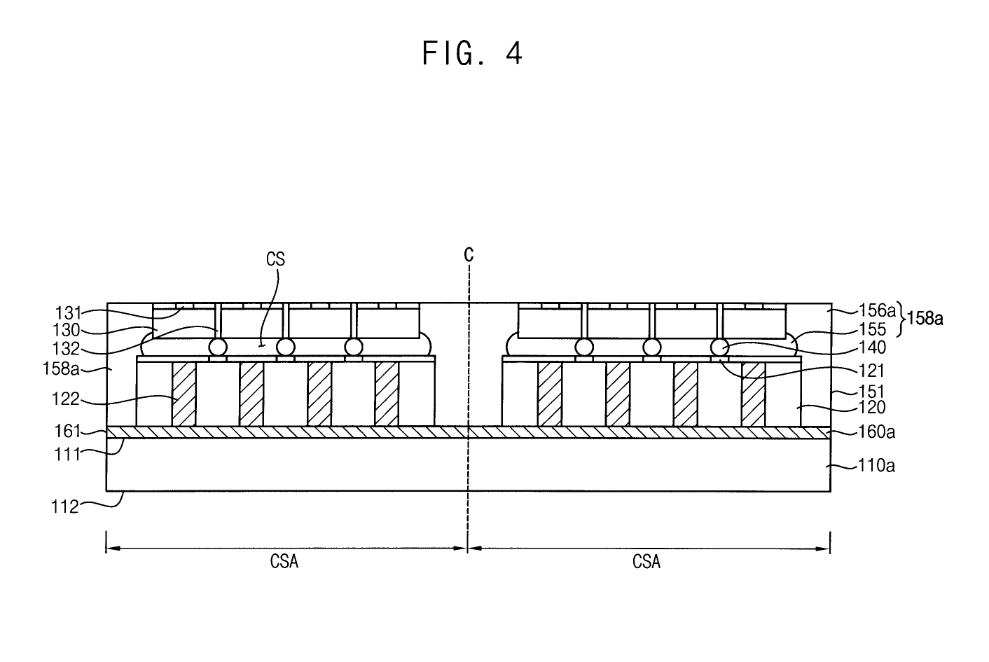

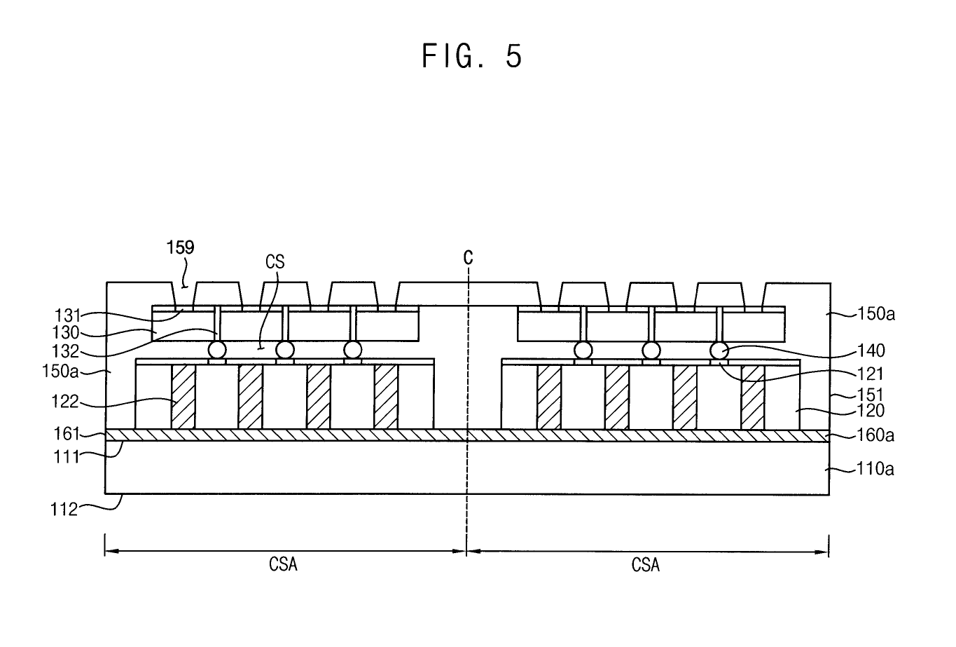

FIG. 4 is a cross-sectional view illustrating a process for forming the preliminary mold layer shown in FIG. 3C, according to another example embodiment.

Referring to FIG. 4, a die adhesive 155 may be coated on an entire active face of the second integrated circuit chip 120 and the inter-chip connector 140 of the first integrated circuit chip 130 may be aligned with the second chip pad 121 of the second integrated circuit chip 120. Thereafter, a thermal compression bonding process may be performed to the first integrated circuit chip 130. Thus, the inter-chip space CS may be filled with the die adhesive 155 and the inter-chip connector 140 may be bonded to the second chip pad 121. The die adhesive 155 may be pressed out from the inter-chip gap space CS.

Then, a preliminary outer mold layer 156a may be formed on the thermal conductive mother plate 110a such that the side space SS of the chip assembly CA may be filled with insulating resins. For example, the preliminary outer mold layer 156a may be performed by an epoxy molding process. A liquefied EMC may be supplied into the side space SS of the neighboring chip assemblies CA to a thickness sufficient to cover the side portion of the chip assembly CA and then a hardening process may be performed to the liquefied EMC in the side space SS. Therefore, a preliminary modified mold layer 158a may be formed to have the die adhesive 155 and the preliminary outer mold layer 156a.

While the present example embodiment discloses that the inter-chip gap space CS may be filled with the die adhesive 155, any other insulating materials known to one of the ordinary skill in the art may be additionally or alternatively supplied into the inter-chip gap space CS. For example, the inter-chip gap space CS may be filled with insulating resins in place of the die adhesive 155 as an inter-chip under-fill (not shown).

Referring to FIG. 3C again, an upper surface of the preliminary mold layer 150a may be coplanar with the first chip pad 131 of the first integrated circuit chip 130 or may be stepped over from the first chip pad 131. When the preliminary mold layer 150a is stepped over the first chip pad 131, the preliminary mold layer 150a may be formed to have a thickness sufficient to cover the first chip pad 131 and may be patterned to have an opening 159 through which the first chip pad 131 is exposed.

FIG. 5 is a cross-sectional view illustrating a process for forming the preliminary mold layer shown in FIG. 3C, according to still another example embodiment.

Referring to FIG. 5, the preliminary mold layer 150a may be formed on the thermal conductive mother plate 110a to have a thickness sufficient to cover the chip assembly CA such that the first chip pad 131 may also be covered with the preliminary mold layer 150a. In such a case, the preliminary mold layer 150a may need to be partially removed from the active face of the first integrated circuit chip 130 to form an opening 159, through which the first chip pad 131 of the first integrated circuit chip 130 is exposed. For example, a drilling process or a photolithography process may be used for partially removing the preliminary mold layer 150a from the active face of the first integrated circuit chip 130.

Because an overall thickness of the multichip package 500 may be mainly determined by a thickness of the preliminary mold layer 150a, the preliminary mold layer 150a may be desired to have a proper thickness in view of the overall thickness of the multichip package 500. Therefore, the overall thickness of the multichip package 500 may be controlled by varying the thickness of the preliminary mold layer 150a of the multichip package 500.

Referring to FIG. 3D, a plurality of conductive bump structures 400 may be formed on the preliminary chip stack structure 100a.

For example, an insulating buffer layer (not shown) may be formed on the upper surface of the preliminary mold layer 150a and may be patterned into a buffer pattern 401 defining an opening, through which the first chip pad 131 may be exposed. A seed layer (not shown) may be formed on the buffer pattern 401 by, e.g., a sputtering process, and then the seed layer may be partially removed from buffer pattern 401 such that the seed layer selectively remain on the first chip pad 131 in the opening. Thereafter, conductive metals may be electroplated on the residual seed layer in the opening, thereby forming the bump structure 400 bonding to the first chip pad 131. Examples of the conductive metals may include, for example, copper (Cu) and lead (Pb).

Referring to FIG. 3E, the preliminary chip stack structure 110a may be separated into pieces by each chip assembly CA, thereby forming a chip stack structure 100. For example, the thermal conductive mother plate 110a may be cut along the cutting line C into pieces corresponding to respective chip stack areas CSA. Thus, the thermal conductive mother plate 110a, the preliminary adhesive 160a and the preliminary mold layer 150a may be separated into individual the dissipating plates 110, individual dissipating adhesives 160 and individual mold layers 150 by the respective chip stack areas CSA. Therefore, a single chip assembly CA may include a dissipating plate 110, mold layers 150 at both sides, and a dissipating adhesive 160 that secures the chip assembly CA to the dissipating plate 110, thereby forming the chip stack structure 100 as shown in FIG. 1. For example, the thermal conductive mother plate 100a, the preliminary adhesive 160a and the preliminary mold layer 150a may be separated into pieces by, for example, a cutting wheel or a laser.

Because the thermal conductive mother plate 110a, the preliminary mold layer 150a and the preliminary adhesive 160a may be separated along the cutting line C substantially perpendicular to the contact face 111 of the thermal conductive mother plate 110a, a sidewall 151 of the mold layer 150, a side surface 161 of the dissipating adhesive 160, and a side surface 113 of the dissipating plate 110 may be coplanar with one another.

In the present example embodiment, the bump structures 400 is formed on the preliminary chip stack structure 100a, and the preliminary chip stack structure 100a including the bump structures 400 is separated into the chip stack structure 100 including the bump structures 400. In some example embodiments, however, the preliminary chip stack structure 100a may be separated into the chip stack structure 100, and the bump structures 400 may be individually formed on the each of the separated chip stack structures 100.

Referring to FIG. 3F, the chip stack structure 100 may be mounted onto a circuit board 200 having electronic circuit pattern therein such that the first integrated circuit chip 130 may be bonded to the circuit board 200.

For example, a bonding agent such as a flux (not shown) may be coated on the bump structures 400 and the chip stack structure 100 may be moved over the circuit board 200 such that the bump structures 400 may be aligned with contact pads 204 of the circuit board 200. Then, the chip stack structure 100 may move downwards and be temporarily combined to the contact pad 204 of the circuit board 200. A heat treatment (e.g., a reflow process) may be performed on the chip stack structure 100 and the circuit board 200 so that the bump structure 400 may be melted around the contact pad 204 of the circuit board 200. Thereafter, a hardening process may be performed on the chip stack structure 100 and the circuit board 200 for a desired time, and the bump structure 400 may be stably bonded to the contact pad 204 of the circuit board 200.

Accordingly, the first and the second integrated circuit chips 130 and 120 may be mounted onto the circuit board 200 by a single mounting process as the chip stack structure 100. Thus, the warpage of the circuit board 200 may be minimized in a mounting process for mounting the first and the second integrated circuit chips 130 and 120 onto the circuit board 200.

When the first integrated circuit chip 130 may be individually mounted onto the circuit board 200 by a thermal treatment (e.g., the reflow process), the difference of the thermal expansion coefficients may be relatively large between the circuit board 200 and the first integrated circuit chip 130, and thus the circuit board 200 may be severely deflected by the first integrated circuit chip 130 and bonding between the first integrated circuit chip 130 and the circuit board 200 may be deteriorated due to the deflection of the circuit board 200. In contrast, in the case that the chip stack structure 100 may be mounted onto the circuit board 200 by the same or similar thermal treatment (e.g., reflow process), the difference of the thermal expansion coefficients between the circuit board 200 and the chip stack structure 100 may be significantly reduced and as a result, the deflection of the circuit board 200 may be substantially minimized. In particular, the second integrated circuit chip 120 having a relatively large size may be firstly combined to the dissipating plate 110 of which the rigidity and the thermal resistance may be higher than the circuit board 200 and then the first integrated circuit chip 130 having a relatively small size may be secondly bonded to the second integrated circuit chip 120. Therefore, the bonding failures between the first integrated circuit chip 130 and the circuit board 200 caused by the warpage of the circuit board 200 may be substantially reduced or prevented, thereby increasing reliability of the multichip package 500.

Referring to FIG. 3G, an under-fill layer 300 may be formed between the chip stack structure 100 and the circuit board 200 such that a gap space S between the circuit board 200 and the first integrated circuit chip 130 may be filled with the under-fill layer 300 and a side surface 301 of the under-fill layer 300 may be connected to the sidewall 151 of the mold layer 150.

For example, a liquefied resin mixture including a resin (e.g., epoxy and urethane), a hardening agent, and a dissipating filling agent (e.g., silica) may be supplied into the gap space S and may be hardened in a hardening process for a desired time, thereby forming the under-fill layer 300 in the gap space S.

The under-fill layer 300 may mitigate or prevent the deflection or the warpage of the circuit board 200 and may protect the chip stack structure 300 from surroundings. Further, operation heat from the chip stack structure 100 may be dissipated outwards via the dissipating filling agent included in the under-fill layer 300. In case that heat dissipation through the under-fill layer 300 is negligible in view of the operation conditions of the multichip package 500, the resin mixture of the under-fill layer 300 may not include the dissipating filling agent.

Because the chip assembly CA may be covered by the mold layer 150 in the chip stack structure 100, the side surface of the under-fill layer 300 may be connected to the sidewall 151 of the mold layer 150, not a side portion of the first integrated circuit chip 130.

According to the conventional packing process for manufacturing the multichip package, the first integrated circuit chip may be individually mounted onto the circuit board and the under-fill layer may be formed in the gap space between the circuit board and the first integrated circuit chip. Thus, the side surface of the under-fill layer may be connected to the side portion of the first integrated circuit chip. In contrast, according to some example embodiments of the present inventive concepts, the chip stack structure 100 including the first integrated circuit chip 130, not the individual first integrated circuit chip 130, is mounted onto the circuit board 200. Thus, the side surface of the under-fill layer 300 may be connected to the sidewall of the mold layer 300, not to the side portion of the first integrated circuit chip 130.

Accordingly, a larger surface area of the circuit board 200 may make contact with the under-fill layer 300 and thus the thermal resistance of the circuit board 200 may be increased in the under-fill process. Further, the mechanical bonding force between the circuit board 200 and the chip stack structure 100 may be increased due to the increase of the surface area of the under-fill layer 300, which may increase reliability of the multichip package 500.

According to the above example embodiments of the method of manufacturing the semiconductor package, the chip assembly CA may be firstly combined to the dissipating plate 110 and then the chip stack structure 100 may be secondly mounted to the circuit board 200. Thus, the warpage of the circuit board 200 may be substantially reduced as compared with when the first integrated circuit chip 130 having a relatively small size is firstly mounted on the circuit board 200 and then the second integrated circuit chip 120 having a relatively large size is bonded to the first integrated circuit chip 130. Therefore, the bonding failures of the integrated circuit chips to the circuit board due to the warpage may be substantially reduced, thereby increasing reliability of the multichip package 500.

Further, because the chip stack structure 100 including the mold layer 150 may be mounted onto the circuit board 200, the surface area of the under-fill layer 300 may be increased. Thus, the thermal resistance of the circuit board 200 may be increased in the under-fill process and thus the warpage of the circuit board 200 may be prevented in the under-fill process. Further, the mechanical bonding force between the circuit board 200 and the chip stack structure 100 may be increased due to the increase of the surface area of the under-fill layer 300, which may increase the reliability of the multichip package 500.

Electronic System Having the Multichip Package

The above example embodiments of the multichip package may be applied to various electronic components and systems.

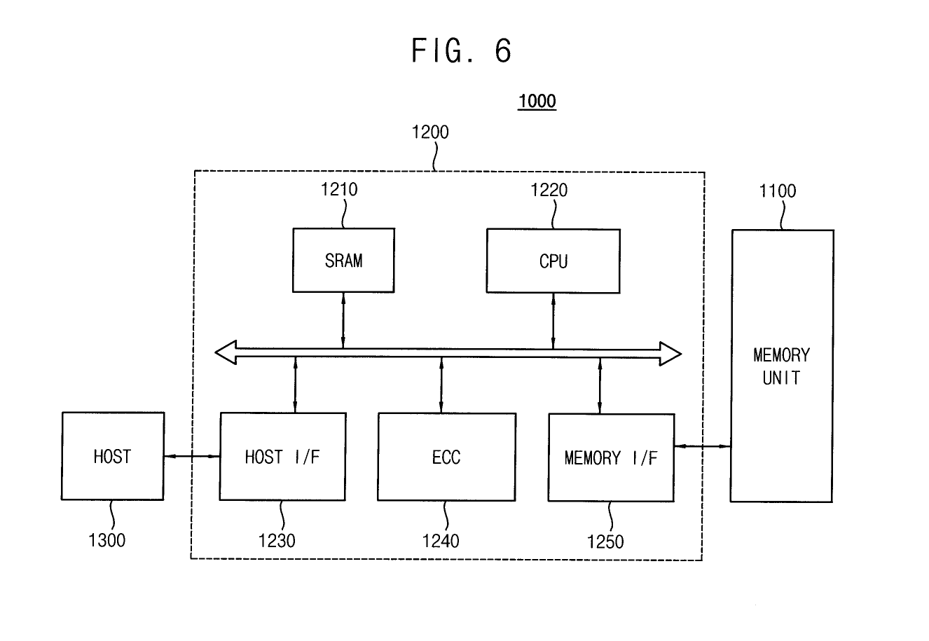

FIG. 6 is a block diagram illustrating a memory card having the semiconductor package shown in FIG. 1 or 2 in accordance with an example embodiment.

Referring to FIG. 6, the memory card 1000 in accordance with an example embodiment may include the semiconductor package shown in FIGS. 1 and 2. For example, the memory card 1000 may include a host 1300, a memory unit 1100 for storing data, and a memory controller 1200 for controlling data transfer between the memory unit and the host 1300.

The memory unit 1100 may include a plurality of memory chips to which electronic data may be transferred from the external host 1300. The electronic data may be stored in the memory unit 1100. The memory chips included in the memory unit 1100 may include, for example, a plurality of DRAM chips or flash memory chips. The host 1300 may include various external electronic systems for processing the electronic data. For example, the host 1300 may include a computer system and a mobile system of which the data storage space may be extendable.

The memory controller 1200 may be connected to the host 1300 and may control the data transfer between the memory unit 1100 and the host 1300.

The memory controller 1200 may include a central process unit (CPU) 1220 for processing the control of data transfer between the host 1300 and the memory unit 1100 and a static random access memory (SRAM) device 1210 as an operational memory device for the CPU 1220. Further, the memory controller 1200 may further include a host interface 1230 having a data transfer protocol of the host 1300, an error correction code 1240 for detecting and correcting errors of the electronic data in the memory unit 1100 and a memory interface 1250 connected to the memory unit 1100.

The SRAM 1210 and the CPU 1220 may be combined to a dissipating plate as the chip assembly CA and thus may be provided as the chip stack structure of the semiconductor package shown in FIG. 1 or 2. That is, the CPU 1220 may function as the first integrated circuit chip 130 of the multichip package 500 and the SRAM 1210 may function as the second integrated circuit chip 120 of the semiconductor package shown in FIG. 1 or 2. The chip stack structure including the SRAM 1210 and the CPU 1220 may be mounted onto a circuit board or a mother board of the memory card 1000. In the present example embodiment, the SRAM 1210 and the CPU 1220 may be stacked on the same circuit board onto which the host interface 1230 and the memory interface 1250 may be mounted such that the memory controller 1200 may be structured into a system-in-package (SIP) to reduce the size and/or increase the operation speed of the memory card 1000. For example, the warpage of the circuit board and the bonding failures caused by the warpage of the circuit board may be substantially reduced due to the bulk mounting of the SRAM 1210 and the CPU 1220, and thus reliability of the memory card 1000 may be substantially increased.

Further, a plurality of memory chips may be stacked on a single dissipating plate and may be secured to the dissipating plate by a mold layer as the chip stack structure 100 of the semiconductor package shown in FIG. 1 or 2. The memory unit 1100 may be manufactured by mounting the memory chip stack structure (not by mounting the memory chip individually or individually mounting the memory chip in a sequential manner) onto a circuit board. Thus, the warpage of the circuit board may be substantially mitigated or prevented in the mounting process, and the bonding failures between the circuit board and memory chips may be substantially reduced, thereby substantially increasing operational reliability of the memory card 1000.

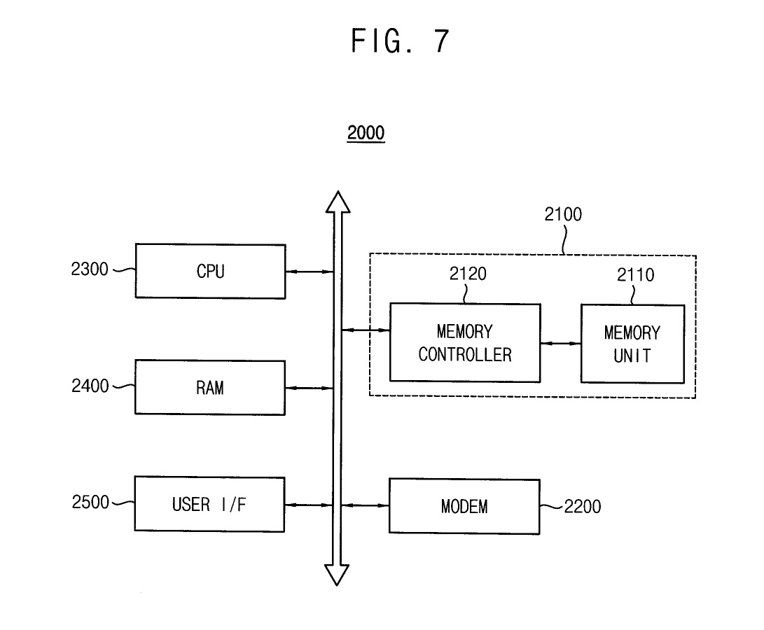

FIG. 7 is a block diagram illustrating an electronic system having the semiconductor package shown in FIG. 1 or 2 in accordance with an example embodiment.

Referring to FIG. 7, the electronic system 2000 in accordance with an example embodiment may include the multichip package shown in FIGS. 1 to 2. For example, the present example embodiment, a memory system 2100 includes the multichip package shown in FIGS. 1 to 2.

The electronic system 2000 may include various mobile systems (e.g., a smart phone and a tablet computer) and traditional computer systems (e.g., a laptop computer system and a desktop computer system). For example, the electronic system 2000 may include the memory system 2100 and a MODEM 2200, a CPU 2300, a RAM device 2400 and a user interface 2500 that may be electrically connected to the memory system 2100 via a system bus line 2600.

The memory system 2100 may include a memory unit 2110 and a memory controller 2120. The memory unit 2110 and the memory controller 2120 may have the same structure as the memory card 1000 shown in FIG. 6, and thus the memory unit 2110 and the memory controller 2120 may be the same multichip package as described in detail with reference to FIGS. 1 to 2. The memory system 2100 may store electronic data that may be processed at the CPU 2300 or may be transferred from the external data source.

Thus, the warpage of the circuit board may be substantially mitigated or prevented in the mounting process and the bonding failures between the circuit board and the memory chips may be substantially reduced, thereby substantially increasing operational reliability of the electronic system 2000 including the memory unit 2110.

The electronic system 2000 may be, for example, a memory card, a solid state disk, a camera image sensor and various application chipsets (AP). For example, when the solid state disk (SSD) is used as the memory system 2100, the electronic system 2000 may process and store a relatively great volume of data with relatively high stability and reliability.

According to the above example embodiments of the present inventive concepts, a plurality of integrated circuit chips may be firstly stacked on a dissipating plate and then a chip stack structure of the integrated circuit chip and the dissipating plate may be secondly mounted onto the circuit board such that a plurality of integrated circuit chips may be mounted the circuit board in a bulk. Thus, the warpage of the circuit board and the bonding failures caused by the warpage may be substantially mitigated or prevented and operational reliability of the semiconductor package may be substantially increased.

According to the above example embodiments of the present inventive concepts, a plurality of integrated circuit chips is firstly combined to the dissipating plate 110 as the chip assembly CA and then the chip stack structure 100 is secondly mounted to the circuit board 200. Thus, the warpage of the circuit board 200 may be substantially reduced as compared with when the first integrated circuit chip 130 having a relatively small size is firstly mounted on the circuit board 200 and then the second integrated circuit chip 120 having a relatively large size is bonded to the first integrated circuit chip 130. Therefore, the bonding failures of the integrated circuit chips to the circuit board caused by the warpage may be substantially reduced, thereby increasing reliability of the multichip package 500.

Further, because the chip stack structure 100 including the mold layer 150 may be mounted onto the circuit board 200, the surface area of the under-fill layer 300 may be increased. Thus, the thermal resistance of the circuit board 200 may be increased in the under-fill process and thus the warpage of the circuit board 200 may be substantially mitigated or prevented in the under-fill process. Further, the mechanical bonding force between the circuit board 200 and the chip stack structure 100 may be increased due to the increase of the surface area of the under-fill layer 300, thereby increasing reliability of the multichip package 500.

The present example embodiments of the multichip package may be applied to various electronic appliances having a plurality of memory chips. For example, the multichip package may be applied to small-sized mobile systems, for example, a digital camcorder, a smart phone, a notebook computer and a memory card. Further, the multichip package may be applied to a logic package (e.g., a digital signal processor, an application specific integrated circuit (ASIC) and a micro controller) in which at least a logic chip and a plurality of memory chips is stacked, and to a memory package (e.g., DRAM devices and flash memory devices) in which a plurality of memory chips is stacked.

The foregoing is illustrative of some of example embodiments and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor package comprising:
a chip stack structure having first and second integrated circuit chips that are secured to a thermal conductive plate using a mold layer such that the second integrated circuit chip is combined to the thermal conducive plate, the first integrated circuit chip is bonded to the second integrated circuit chip, and the first integrated circuit chip has a smaller thickness than the second integrated circuit chip;
a circuit board onto which the chip stack structure is mounted in a bonded manner; and
an under-fill layer filling a gap space between the circuit board and the first integrated circuit chip, a side surface of the under-fill layer connected to a sidewall of the mold layer.

2. The semiconductor package of claim 1, wherein the first integrated circuit chip includes a wafer level chip having at least one penetration electrode penetrating therethrough and the second integrated circuit chip includes a die level chip having no penetration electrode.

3. The semiconductor package of claim 2, further comprising:
at least one inter-chip connector between the first and the second integrated circuit chips, the inter-chip connector configured to connect the penetration electrode of the first integrated circuit chip with a chip pad of the second integrated circuit chip.

4. The semiconductor package of claim 3, further comprising:
a die adhesive between the first and the second integrated circuit chips to attach the first and the second integrated circuit chips to each other.

5. The semiconductor package of claim 1, wherein the thermal conductive plate includes a dissipating plate dissipating heat outwards from at least one of the first and the second integrated circuit chips and a side surface of the thermal conductive plate is coplanar with the sidewall of the mold layer.

6. The semiconductor package of claim 5, further comprising:
a thermal conductive adhesive for adhering the dissipating plate to the second integrated circuit chip, the thermal conductive adhesive configured to transfer the heat to the dissipating plate.

7. The semiconductor package of claim 1, further comprising:
a plurality of bump structures between a first chip pad of the first integrated circuit chip and an upper contact pad of the circuit board, the bump structures configured to electrically connect the first integrated circuit chip to the circuit board.

8. A method of manufacturing a semiconductor package, comprising:
forming a chip stack structure having at least one first integrated circuit chip and at least one second integrated circuit chip that are secured to a thermal conductive mother plate using a mold layer such that the second integrated circuit chip is combined to the thermal conductive mother plate, the first integrated circuit chip is bonded to the second integrated circuit chip, and the first integrated circuit chip has a smaller thickness than the second integrated circuit chip;
mounting the chip stack structure onto a circuit board such that the first integrated circuit chip is bonded to the circuit board; and
forming an under-fill layer to fill a gap space between the chip stack structure and the circuit board, a side surface of the under-fill layer being connected to a sidewall of the mold layer.

9. The method of claim 8, wherein forming the chip stack structure includes:
combining a plurality of the second integrated circuit chips to the thermal conductive mother plate, the plurality of the second integrated circuit chips including the at least one second integrated circuit chip;
forming a plurality of chip assemblies on the thermal conductive mother plate by bonding a plurality of the first integrated circuit chips to the second integrated circuit chips, respectively such that at least one penetration electrode penetrating one of the first integrated circuit chips is bonded to a corresponding one of the second integrated circuit chips, the plurality of the first integrated circuit chips including the at least one first integrated circuit chip;
forming a mold layer to cover the chip assemblies to secure the chip assemblies to the thermal conductive mother plate, thereby forming a preliminary chip stack structure; and
separating the preliminary chip stack structure into pieces by each of the chip assemblies.

10. The method of claim 9, wherein forming the plurality of the chip assemblies on the thermal conductive mother plate includes:
forming at least one inter-chip connector on a rear face of one of the first integrated circuit chips such that the inter-chip connector is bonded to the penetration electrode of the one of the first integrated circuit chips;
positioning the one of the first integrated circuit chips over a corresponding one of the second integrated circuit chips such that the inter-chip connector of the one of the first integrated circuit chips is aligned with a chip pad of the corresponding one of the second integrated circuit chips; and
bonding the inter-chip connector of the one of the first integrated circuit chips to the chip pad of the corresponding one of the second integrated circuit chips.

11. The method of claim 10, wherein bonding the inter-chip connector includes supplying a die adhesive into an inter-chip gap space between the first and the second integrated circuit chips and performing a thermal compression bonding process.

12. The method of claim 9, wherein forming the mold layer include covering the chip assemblies with a liquefied epoxy molding compound and hardening the liquefied epoxy molding compound.

13. The method of claim 9, wherein forming the mold layer is performed by a single molded under fill (MUF) process in which an inter-chip gap space between the first and the second integrated circuit chips and a side space between the neighboring chip assemblies are filled with a same molding material.

14. The method of claim 9, further comprising:
before separating the preliminary chip stack structure into the pieces, forming at least one bump structure on at least one chip pad of the first integrated circuit chips.

15. The method of claim 14, wherein mounting the chip stack structure onto the circuit board includes coating at least one contact pad of the circuit board with a flux, aligning the bump structure with the contact pad, and bonding the bump structure to the contact pad of the circuit board.

16. A semiconductor package comprising:
a chip stack structure including a first semiconductor chip, a second semiconductor chip, a thermal conductive plate, and a mold layer, the second semiconductor chip between the first semiconductor chip and the thermal conductive plate, the first semiconductor chip thinner than the second semiconductor chip, the mold layer covering the first and second semiconductor chips on the thermal conductive plate;
a circuit board onto which the chip stack structure is attached such that a chip pad of the first semiconductor chip is coupled to an upper contact pad of the circuit board through a conductive structure; and
an under-fill layer filling a gap space between the circuit board and the first semiconductor chip, a side surface of the under-fill layer extending from a sidewall of the mold layer.

17. The semiconductor package of claim 16, wherein the second semiconductor chip is larger than the first semiconductor chip.

18. The semiconductor package of claim 16, wherein an upper surface of the mold layer is coplanar with the chip pad of the first semiconductor chip or stepped over the chip pad.

19. The semiconductor package of claim 16, wherein a sidewall of the chip stack structure is defined by the mold layer and has a substantially vertical shape.

20. The semiconductor package of claim 16, wherein the first semiconductor chip includes a wafer level chip, the first semiconductor chip has at least one penetrating electrode penetrating therethrough, and the second semiconductor chip includes a die level chip having no penetration electrode.
